(19) United States
(12) Patent Application Publication
(10) Pub. No.: US 2006/0255369 A1
(43) Pub. Date: Nov. 16, 2006

(54) High-voltage semiconductor device and method of manufacturing the same

(75) Inventors: Yong-Chan Kim, Suwon-si (KR); Yong-Don Kim, Suwon-si (KR); Joon-Hyung Lee, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/430,580

(22) Filed: May 9, 2006

(30) Foreign Application Priority Data
May 13, 2005 (KR) 2005-39934

(51) Int. Cl. H01L 29/768

(52) U.S. Cl. 257/219

(57) ABSTRACT

A high-voltage semiconductor device and a method of manufacturing the high-voltage semiconductor device are provided. For example, with the above device and method drift regions having first depths are formed in a semiconductor substrate by doping first impurities. The drift regions are spaced apart from each other to define a channel region between the drift regions. Source/drain regions having second depths are formed at first portions of the drift regions by doping second impurities. Impurity accumulation regions having third depths are formed at second portions of the drift region adjacent to the source/drain regions by doping third impurities. A gate insulation layer pattern is formed on the semiconductor substrate to partially expose the source/drain regions. A gate conductive layer pattern is formed on a portion of the gate insulation layer pattern where the channel region is positioned. A buffer layer capable of preventing a rapid increase of a current is formed on the gate structure and the gate insulation layer pattern.

### CROSS REFERENCE TO RELATED APPLICATION

This application claims benefit of priority under 35 U.S.C. § 119 from Korean Patent Application No. 2005-39934 filed on May 13, 2005, the disclosure of which is hereby incorporated by reference herein in its entirety.

### BACKGROUND OF THE INVENTION

1. Field of the Invention

The present invention relates to a high-voltage semiconductor device and a method of manufacturing the high-voltage semiconductor device. More particularly, the present invention relates to a high-voltage semiconductor device which may be formed together with a complementary metal oxide semiconductor (CMOS) device on one semiconductor substrate.

2. Description of the Related Art

Continuing innovations in semiconductor manufacturing technology is allowing semiconductor devices to be developed with higher integration densities. For example, an active device such as a high-voltage semiconductor device may be formed together with a logic device such as a complementary metal oxide semiconductor (CMOS) device on one semiconductor substrate.

FIG. 1 is a cross-sectional view illustrating the conventional high-voltage semiconductor device formed together with a conventional CMOS device on one semiconductor substrate.

Referring to FIG. 1, the conventional CMOS device and the conventional high-voltage semiconductor device are formed on a semiconductor substrate 10. The semiconductor substrate 10 is divided into a CMOS area and a high-voltage area. The CMOS and the high-voltage semiconductor devices are formed in the CMOS and the high-voltage areas, respectively. Moreover, the semiconductor substrate 10 is further divided into an active region and a field region by the formation of an isolation layer 12.

The CMOS device formed in the CMOS area of the semiconductor substrate 10 includes a first transistor having a first gate structure 19 and first source/drain regions 14a and 14b. The first gate structure 19 includes a first gate insulation layer pattern 16 and a first gate conductive layer pattern 18. The first transistor further includes a first spacer 21 formed on a sidewall of the first gate structure 19. Additionally, the first transistor includes metal silicide layers 20a and 20b formed on the first gate conductive layer pattern 18 and a portion 14a of the first source/drain regions 14a and 14b.

The CMOS device further includes a first insulation layer pattern 24 covering the first gate structure 19 in the CMOS area, and a first conductive layer pattern 26 formed through the first insulation layer pattern 24. The first insulation layer pattern 24 includes a first opening 23 that partially exposes the metal silicide layer 20b formed on the portion 14a of the first source/drain regions 14a and 14b. The first conductive layer pattern 26 is formed on the first insulation layer pattern 24 to fill up the first opening 23.

The high-voltage semiconductor device formed in the high-voltage area of the semiconductor substrate 10 includes a second transistor having a second gate structure 39 and second source/drain regions 32a and 32b. The second gate structure 39 includes a second gate insulation layer pattern 36 and a second gate conductive layer pattern 38. The second transistor further includes drift regions 34a and 34b that enclose the second source/drain regions 32a and 32b, respectively. The drift regions 34a and 34b have impurity concentrations lower than those of the second source/drain regions 32a and 32b.

The second gate insulation layer pattern 36 has a width wider than that of the second gate conductive layer pattern 38 so that the second gate insulation layer pattern 36 covering the drift regions 34a and 34b exposes the second source/drain regions 32a and 32b.

The second transistor positioned in the high-voltage area of the semiconductor substrate 10 further includes a second spacer 41, a second insulation layer pattern 44 and second conductive layer patterns 46a and 46b. The second spacer 41 is formed on a sidewall of the second gate conductive layer pattern 38. The second insulation layer pattern 44 has second openings 43a and 43b that partially expose the second source/drain regions 32a and 32b. The second conductive layer patterns 46a and 46b are formed on the second insulation layer pattern 44 to fill up the second openings 43a and 43b, respectively.

The second transistor further includes a buffer layer 48 formed on the second gate structure 39 and the second gate insulation layer pattern 36. Particularly, the buffer layer 48 is positioned on the second gate conductive layer pattern 38, the second spacer 41 and the second gate insulation layer pattern 36. The buffer layer 48 is in the high-voltage area when the metal silicide layers 20a and 20b serving as etch stop layers or silicidation preventing layers are formed in the CMOS area.

The buffer layer 48 is formed using silicon nitride or silicon oxynitride. However, with the above-described high-voltage semiconductor device, charge trapping sites may be generated at an interface between the buffer layer 48 and the second gate insulation layer pattern 36 during operation of the high-voltage semiconductor device when the buffer layer 48 is formed in the high-voltage area. For example, when the charge trapping sites are formed, a current in the high-voltage semiconductor device may be rapidly increased because resistances of the drift regions 34a and 34b are reduced, thereby causing the reliability of the high-voltage semiconductor device to deteriorate.

However, the above-mentioned difficulties may be overcome by not forming a buffer layer in a current high-voltage semiconductor device, and by not forming an etch stop layer in a CMOS device. Nevertheless, when the buffer layer and the etch stop layer are not formed, the design rule of the CMOS device may be deteriorated. Furthermore, even though a buffer layer in the high-voltage semiconductor device may be removed without also removing an etch stop layer in the CMOS device, this type of manufacturing process may be complicated because, with this conventional process, an active device such as the high-voltage semiconductor device and a logic device such as the CMOS device may not be properly formed on one semiconductor substrate.

Thus, there is a need for a high-voltage semiconductor device which includes a buffer layer and which may prevent a rapid increase of a current flowing in the high-voltage semiconductor device caused by charge trapping sites, and which may be formed together with a complementary metal oxide semiconductor (CMOS) device on one semiconductor substrate.

### SUMMARY OF THE INVENTION

In accordance with an exemplary embodiment of the present invention, a high-voltage semiconductor device is provided. The high-voltage semiconductor device includes a semiconductor substrate and a plurality of drift regions formed in the semiconductor substrate. Each of the plurality of drift regions formed has a first impurity, a first impurity concentration and a first depth. In addition, the drift regions are separate from each other to define a channel region between the drift regions. The high-voltage semiconductor device further includes a source region and a drain region formed at first portions of the drift regions. The source region and the drain region formed each have a second impurity, a second impurity concentration and a second depth, wherein the second depths of the source/drain regions are substantially smaller than the first depths. Moreover, the high-voltage semiconductor device further includes a plurality of impurity accumulation regions formed at second portions of the drift regions adjacent to the source/drain regions with each of the plurality of impurity accumulation regions formed have a third impurity, a third impurity concentration and a third depth. The thirds depths of the impurity accumulation regions are substantially smaller than the first depths. The high-voltage semiconductor device also includes a gate structure formed on the semiconductor substrate, wherein the gate structure comprises a gate insulation layer pattern formed on the semiconductor substrate to partially expose the source/drain regions, a gate conductive layer pattern formed on a portion of the gate insulation layer pattern where the channel region is positioned, and a buffer layer formed on the gate structure.

In an exemplary embodiment of the present invention, the high-voltage semiconductor device may further include an isolation layer for dividing the semiconductor substrate into an active region and a field region. The channel region, the drift regions and the gate structure may be positioned on the active region.

In an exemplary embodiment of the present invention, the first, the second and the third impurities may include substantially the same elements. For example, the first, the second and the third impurities include elements in Group III or elements in Group V.

In an exemplary embodiment of the present invention, the second impurity concentrations may be substantially larger than the third impurity concentrations. Additionally, the third impurity concentrations may be substantially larger than the first impurity concentrations.

In an exemplary embodiment of the present invention, the second depths may be substantially deeper than the third depths.

In an exemplary embodiment of the present invention, the source/drain regions may be spaced apart from the channel region.

In an exemplary embodiment of the present invention, the impurity accumulation regions may be adjacent to the source/drain regions whereas the impurity accumulation regions may be spaced apart from the channel region.

In an exemplary embodiment of the present invention, the gate insulation layer pattern may include silicon oxide or metal oxide layer, and the gate conductive layer pattern may include metal, metal nitride or polysilicon doped with impurities. Further, the buffer layer may include silicon nitride or silicon oxynitride.

In an exemplary embodiment of the present invention, the high-voltage semiconductor device may further include a deep well region formed in the semiconductor substrate to enclose the channel region and the drift regions by doping fourth impurities different from the first impurities with a fourth impurity concentration substantially smaller than the first impurity concentrations. The deep well region may have a fourth depth substantially larger than the first depth.

According to another exemplary embodiment of the present invention, a method of manufacturing a high-voltage semiconductor device is provided. The method includes forming a plurality of drift regions in a semiconductor substrate by doping first impurities with first impurity concentrations into the semiconductor substrate, such that each of the plurality of drift regions formed have a first impurity, a first impurity concentration and a first depth, and wherein the drift regions are spaced apart from each other to define a channel region between the drift regions. The method further includes forming a source region and a drain region at first portions of the drift regions by doping second impurities with second impurity concentrations into the first portions of the drift regions such that the source region and the drain region formed each have a second impurity, a second impurity concentration and a second depth, and wherein the second depths of the source/drain regions are substantially smaller than the first depths. Additionally, the method includes forming a plurality of impurity accumulation regions at second portions of the drift regions adjacent to the source/drain regions by doping third impurities with third impurity concentrations into the second portions of the drift regions adjacent to the source/drain regions such that each of the plurality of impurity accumulation regions formed have a third impurity, a third impurity concentration and a third depth, and wherein the third depths of the impurity accumulation regions are substantially smaller than the first depths. Moreover, the method includes forming a gate insulation layer pattern on the semiconductor substrate, wherein the gate insulation layer pattern has openings that partially expose the source/drain regions, forming a gate conductive layer pattern on a portion of the gate insulation layer pattern where the channel region is positioned, and forming a buffer layer on the gate insulation layer pattern and the gate conductive layer pattern.

In an exemplary embodiment of the present invention, an isolation layer may be formed at an upper portion of the semiconductor substrate to define an active region and a field region. Additionally, a deep well region may be formed in the semiconductor substrate to enclose the channel region and the drift regions by doping impurities different from the first impurities with an impurity concentration substantially smaller than the first impurity concentrations. The deep well region may have a fourth depth substantially larger than the first depths.

In an exemplary embodiment of the present invention, the drift regions, the source/drain regions and the impurity accumulation regions may be formed in any particular order.

In an exemplary embodiment of the present invention, the impurity accumulation regions may be formed when impurities for adjusting a threshold voltage are doped into a portion of the semiconductor substrate adjacent to the high-voltage semiconductor device.

In an exemplary embodiment of the present invention, the buffer layer may be formed when an etch stop layer or a silicidation preventing layer is formed on a portion of the semiconductor substrate adjacent to the high-voltage semiconductor substrate.

According to exemplary embodiments of the present invention, a high-voltage semiconductor device includes impurity accumulation regions adjacent to source/drain regions so that the impurity accumulation regions may prevent a rapid increase of a current flowing in the high-voltage semiconductor device caused by charge trapping sites. Therefore, a complementary metal oxide semiconductor (CMOS) device and the high-voltage semiconductor device may be readily formed on one semiconductor substrate.

### BRIEF DESCRIPTION OF THE DRAWINGS

The above and other advantages of the present invention will become readily apparent by reference to the following detailed description when considered in conjunction with the accompanying drawings in which:

FIG. 1 is a cross-sectional view illustrating a conventional high-voltage semiconductor device and a complementary metal oxide semiconductor (CMOS) semiconductor device formed on one semiconductor substrate;

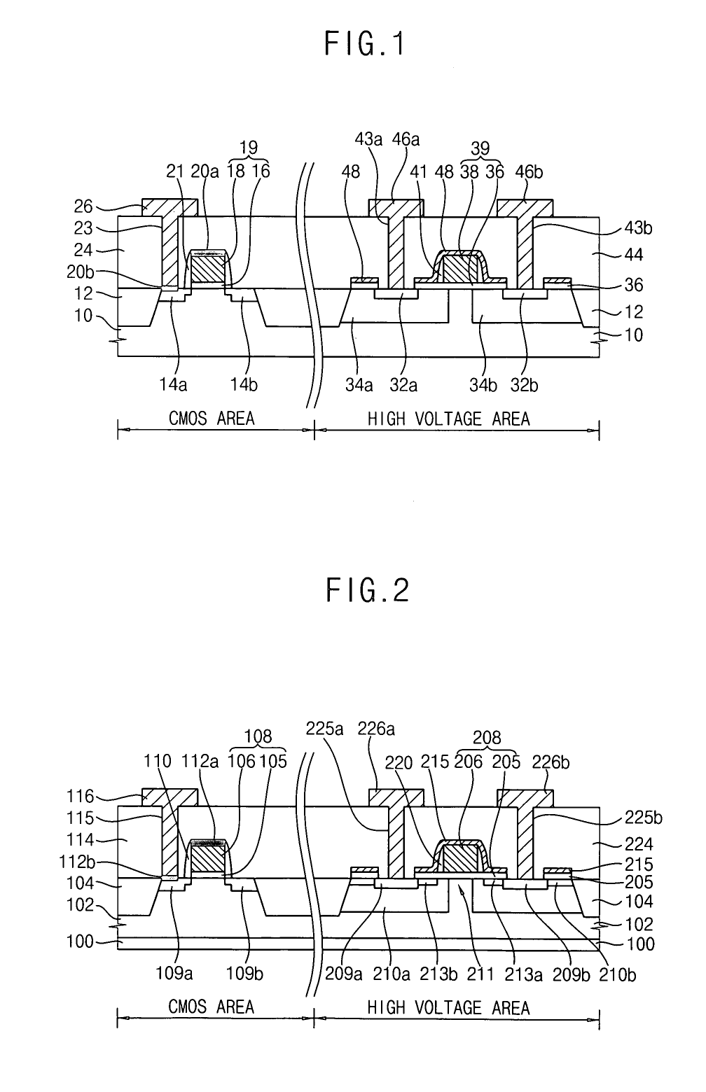

FIG. 2 is a cross-sectional view illustrating a CMOS device and a high-voltage semiconductor device in accordance with an exemplary embodiment of the present invention;

FIGS. 3 to 7 are cross-sectional views illustrating a method of manufacturing a high-voltage semiconductor device in accordance with an exemplary embodiment of the present invention; and

FIG. 8 is a graph showing a variation of a current relative to time in a conventional high-voltage semiconductor device and a high-voltage semiconductor device according to an exemplary embodiment of the present invention.

### DESCRIPTION OF EXEMPLARY EMBODIMENTS

Exemplary embodiments of the present invention will be described with reference to the accompanying drawings. The present invention may, however, be embodied in many different forms and should not be construed as limited to the exemplary embodiments set forth herein.

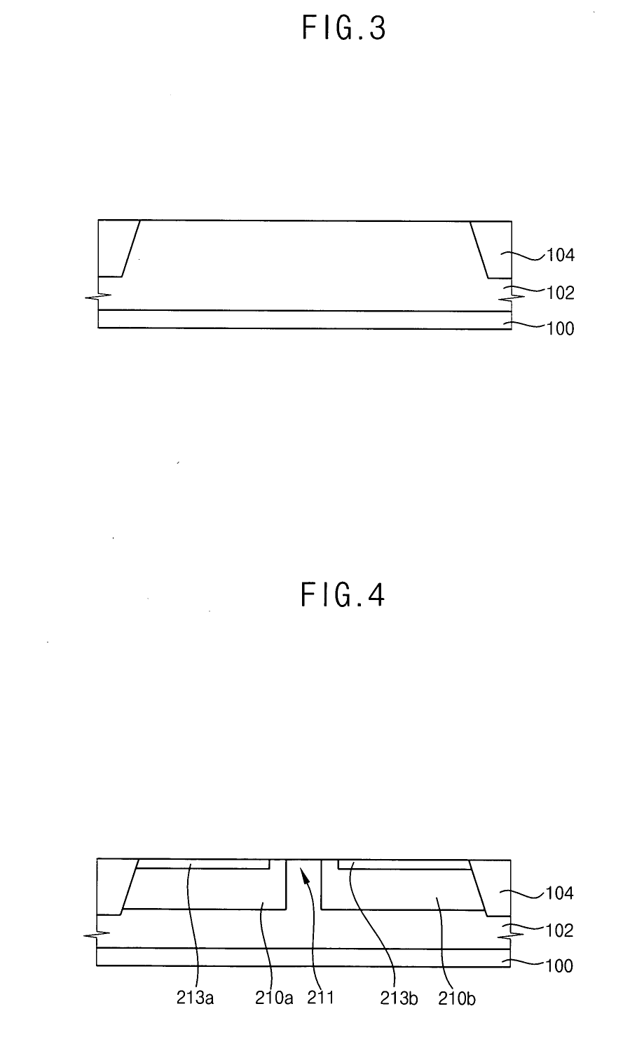

FIG. 2 is a cross-sectional view illustrating a CMOS device and a high-voltage semiconductor device in accordance with an exemplary embodiment of the present invention.

Referring to FIG. 2, a complementary metal oxide semiconductor (CMOS) device and a high-voltage semiconductor device are formed on one semiconductor substrate 100. The semiconductor substrate 100 includes a CMOS area and a high-voltage area. The CMOS device and the high-voltage semiconductor device are formed on the CMOS area and the high-voltage area, respectively.

The semiconductor substrate 100 is divided into active regions and field regions in accordance with a formation of an isolation layer 140 on the semiconductor substrate 100. The isolation layer 104 may be formed using a shallow trench isolation (STI) process.

A deep well region 102 is formed at an entire upper portion of the semiconductor substrate 100 having the CMOS and the high-voltage areas. That is, the deep well region 102 is formed in the CMOS and the high-voltage areas. The deep well region 102 may be formed by doping impurities into the entire upper portion of the semiconductor substrate 100 so that the deep well region 102 may have a relatively low impurity concentration.

The impurities doped into the deep well region 102 may vary in accordance with the type of a semiconductor device such as, e.g., a transistor formed on the deep well region 102. For example, when an N channel metal oxide semiconductor (NMOS) transistor is formed on the deep well region 102, P type impurities may be doped into the deep well region 102. On the other hand, N type impurities may be doped into the deep well region 102 when a P channel metal oxide semiconductor (PMOS) transistor is formed on the deep well region 102. The P type impurities may include, for example, boron (B) or indium (In), and the N type impurities may include, for example, phosphorus (P) or arsenic (As).

In some exemplary embodiments of the present invention, the impurities may be doped into the entire upper portion of the semiconductor substrate 100 to form the deep well region 102 by an ion implantation process. For example, the deep well region 102 may have an impurity concentration of about 1.0×10¹⁰ ions/cm².

The CMOS device formed in the CMOS area of the semiconductor substrate 100 includes a first transistor having a first gate structure 108 and first source/drain regions 109a and 109b.

The first gate structure 108 includes a first gate insulation layer pattern 105 and a first gate conductive layer pattern 106. The first gate insulation layer pattern 105 is formed on the active region of the CMOS area. The first source/drain regions 109a and 109b are formed at upper portions of the active region in the CMOS area. The first source/drain regions 109a and 109b may each have lightly doped drain (LDD) structures, respectively.

The first transistor further includes a first spacer 110 formed on a sidewall of the first gate structure 108. Additionally, the first transistor includes metal suicide layer patterns 112a and 112b formed on the first gate conductive layer pattern 106 and a portion 109a of the first source/drain regions 109a and 109b, respectively.

A first insulation layer pattern 114 is formed on the CMOS area of the semiconductor substrate 100 to cover the first gate structure 108. The first insulation layer pattern 114 has a first opening 115 that partially exposes the portion 109a of the first source/drain regions 109a and 109b where the metal silicide layer pattern 112b is positioned. That is, the metal silicide layer pattern 112b is exposed through the first opening 115.

A first conductive layer pattern 116 is formed on the first insulation layer pattern 114 to fill up the first opening 115. The first conductive layer pattern 116 makes electrical contact with the metal silicide layer pattern 112b.

The high-voltage semiconductor device formed in the high-voltage area of the semiconductor substrate 100 includes a second transistor. The second transistor includes a second gate structure 208 and second source/drain regions 209a and 209b.

The second gate structure 208 includes a second gate insulation layer pattern 205 and a second gate conductive layer pattern 206. The second gate insulation layer pattern 205 may have a width substantially wider than that of the second gate conductive layer pattern 206. That is, the second gate insulation layer pattern 205 may be enlarged more than the second gate conductive layer pattern 206. The second gate insulation layer pattern 205 may be formed on an entire active region of the high-voltage area except for the second source/drain regions 209a and 209b.

The second transistor additionally includes a second spacer 220 formed only on a sidewall of the second gate conductive layer pattern 206. Namely, the second spacer 220 may not cover a sidewall of the second gate insulation layer pattern 205 and a bottom of the second spacer 220 located on the second gate insulation layer pattern 205 because the second gate insulation layer pattern 205 may have the enlarged width as describe above.

In some exemplary embodiments of the present invention, the second source/drain regions 209a and 209b may be spaced apart from a channel region 211 formed at an upper portion of the active region in the high-voltage area of the semiconductor substrate 100 under the second gate conductive layer pattern 206.

The second transistor further includes drift regions 210a and 210b enclosing the second source/drain regions 209a and 209b so that the second source/drain regions 209a and 209b may be efficiently separated from the channel region 211. Since high voltages may be directly applied to the second source/drain regions 209a and 209b of the high-voltage semiconductor device, a punch-through voltage between the second source/drain regions 209a and 209a and the semiconductor substrate 100 may be substantially larger than the high voltage. In addition, a breakdown voltage between the second source/drain regions 209a and 209b and the semiconductor substrate 100 or between the second source/drain regions 209a and 209b and the deep well region 102 may be substantially larger than the high voltage. For this reason, the drift regions 210a and 210b are formed in the high-voltage area to enclose the second source/drain regions 209a and 209b.

In some exemplary embodiments of the present invention, the high-voltage semiconductor impurity accumulation regions 213a and 213b are formed at upper portions of the drift regions 210a and 210b adjacent to the second source/drain regions 209a and 209b, respectively. The impurity accumulation regions 213a and 213b adjacent to the second source/drain regions 209a and 209b are separated apart from the channel region 211. The impurity accumulation regions 213a and 213b may extend under the second gate conductive layer pattern 206.

Additionally, in some exemplary embodiment of the present invention, first impurities may be doped into the upper portions of the high-voltage area of the semiconductor substrate 100 to thereby form the drift regions 210a and 210b. The drift regions 210a and 210b may be formed using an ion implantation process. Each of the drift regions 210a and 210b may have a first impurity concentration and a first depth. When the drift regions 210a and 210b are formed at the upper portions of the high-voltage area, the channel region 211 may be defined by the drift regions 210a and 210b. Second impurities may be doped into the upper portions of the drift regions 210a and 210b to form the second source/drain regions 209a and 209b at the upper portions of the drift regions 210a and 210b, respectively. The second source/drain regions 209a and 209b may be formed using an ion implantation process. The second source/drain regions 209a and 209b may have second impurity concentrations and second depths, respectively. The impurity accumulation regions 213a and 213b may be formed by doping third impurities into upper portions of the drift regions 210a and 210b adjacent to the second source/drain regions 209a and 209b through an ion implantation process. Each of the impurity accumulation regions 213a and 213b may have a third impurity concentration and a third depth.

Moreover, in some exemplary embodiments of the present invention, the second impurity concentrations of the second source/drain regions 209a and 209a may be substantially larger than the third impurity concentrations of the impurity accumulation regions 213a and 213b. In addition, the third impurity concentrations of the impurity accumulation regions 213a and 213b may be substantially larger than the first impurity concentrations of the drift regions 210a and 210. For example, the first impurity concentration may be about 1.0×10¹² ions/cm², the second impurity concentration may be about 1.0×10¹⁵ions/cm² and the third impurity concentration may be about 1.0×10¹³ ions/cm².

When the third depths of the impurity accumulation regions 213a and 213b are substantially deeper than the second depths of the second source/drain regions 209a and 209b, a contact resistance at the second source/drain regions 209a and 209b may be increased. Thus, in the present exemplary embodiment, the second depths of the second source/drain regions 209a and 209b are substantially deeper than the third depths of the impurity accumulation regions 213a and 213b.

Furthermore, in some example embodiments of the present invention, the first impurities, the second impurities and the third impurities may include substantially the same elements. When the second transistor corresponds to a PMOS transistor, the first to the third impurities may include, for example, elements in Group III such as boron (B) or indium (In) so that the first to the third impurities may have P types, respectively. When the second transistor corresponds to an NMOS transistor, the first to the third impurities may include, for example, elements in Group V such as phosphorus (P) or arsenic (As) such that the first to the third impurities may have N types.

The high-voltage semiconductor device further includes a second insulation layer pattern 224 and second conductive layer patterns 226a and 226b, which are positioned in the high-voltage area of the semiconductor substrate 100. The second insulation layer pattern 224 is formed in the high-voltage area to cover the second gate structure 208. Second openings 225a and 225b are formed through the second insulation layer pattern 224 to partially expose the second source/drain regions 209a and 209b, respectively. The second conductive layer patterns 226a and 226b are formed on the second insulation layer pattern 224 to fill up the second openings 225a and 225b.

In some exemplary embodiments of the present invention, the high-voltage semiconductor device further includes a buffer layer 215 formed on the second gate structure 208 and the second gate insulation layer pattern 205. That is, the buffer layer 215 is formed on the second gate conductive layer pattern 206, the second spacer 220 and the enlarged second gate insulation layer pattern 206. The buffer layer 215 may be formed together with an etch stop layer or a silicidation preventing layer formed in the CMOS area during the processes for forming the CMOS device.

Moreover, in some example embodiments of the present invention, second gate insulation layer pattern 205 in the high-voltage area and the first gate insulation layer pattern 105 may be formed using an oxide such as silicon oxide or metal oxide. The first and the second gate conductive layer patterns 106 and 206 may be formed using, for example, polysilicon, metal, or metal nitride and the first and the second spacers 110 and 220 may be formed using, for example, silicon nitride or silicon oxynitride. Additionally, the buffer layer 215 may be formed using, for example, silicon nitride or silicon oxynitride. Furthermore, the first and the second insulation layer patterns 114 and 224 may be formed using an oxide such as, for example, silicon oxide, and the first and the second conductive layer patterns 116, 226a and 226b may be formed using conductive materials such as, for example, metal.

According to some exemplary embodiments of the present invention, the high-voltage semiconductor device includes the impurity accumulation regions 213a and 213b so that a current flowing in the high-voltage semiconductor device may not be rapidly increased even though charge trapping sites may be generated at an interface between the buffer layer 215 and the second gate insulation layer pattern 205. In other words, as a result of the impurity accumulation regions 213a and 213b having third impurity concentrations which are substantially higher than those of the drift regions 210a and 210b, the high-voltage semiconductor device may become dull relative to an increase of the current caused by the charge trapping sites, thereby preventing the current in the high-voltage semiconductor device from rapidly increasing.

As described above, a high-voltage semiconductor device according to exemplary embodiments of the present invention includes impurity accumulation regions adjacent to source/drain regions to thereby prevent a rapid increase of current flowing in the high-voltage semiconductor device caused by charge trapping sites.

Hereinafter, a method of manufacturing a high-voltage semiconductor device in accordance with exemplary embodiments of the present invention will be described with reference to the accompanying drawings.

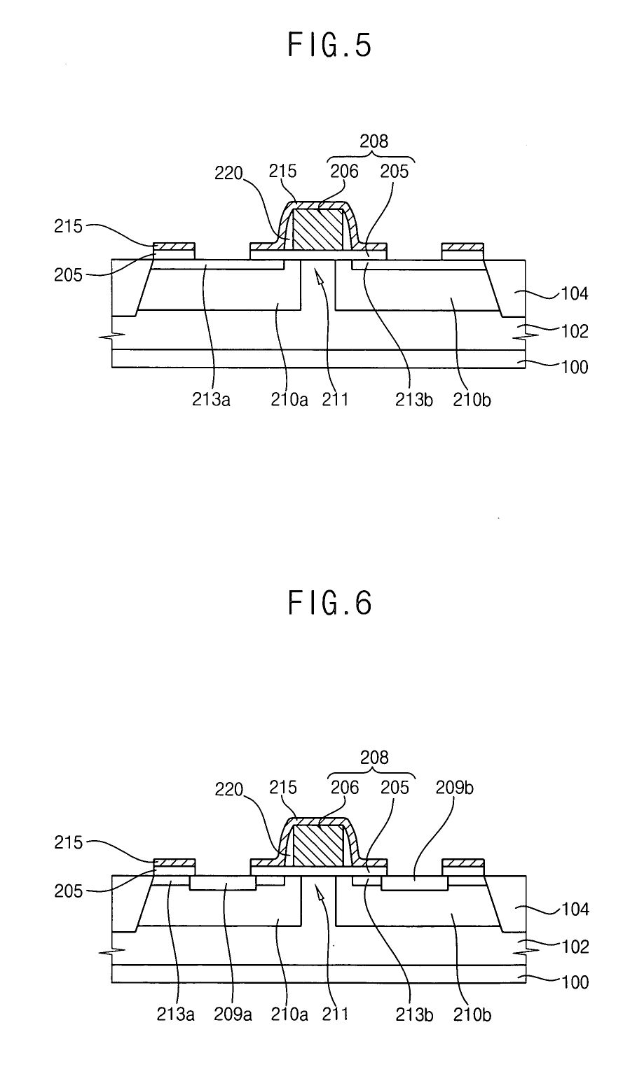

FIGS. 3 to 7 are cross-sectional views illustrating the method of manufacturing a high-voltage semiconductor device in accordance with an exemplary embodiment of the present invention. In FIGS. 3 to 7, the high-voltage semiconductor device corresponds to an NMOS type high-voltage semiconductor device. However, the method according to exemplary embodiments of the present invention may be employed for other high-voltage semiconductor devices as well such as, for example, PMOS type high-voltage semiconductor devices.

Referring to FIG. 3, to form the high-voltage semiconductor device, impurities are doped into a high-voltage area of a semiconductor substrate 100 by an ion implantation process so that a deep well region 102 is formed in the high-voltage area of the semiconductor substrate 100. For example, the impurities such as boron difluoride (BF₂) may be doped with a concentration of about 1.0×10¹⁰ ions/cm² to form the deep well region 102.

An isolation layer 104 is formed on the semiconductor substrate 100 to divide the high-voltage area of the semiconductor substrate 100 into an active region and a field region. The isolation layer 104 may be formed using oxide through an STI process.

Referring to FIG. 4, a first ion implantation process is carried out about an active region of the high-voltage area so that drift regions 210a and 210b are formed at upper portions of the active region. For example, the drift regions 210a and 210b may be formed by implanting first impurities such as phosphorus (P) with a first impurity concentration of about 1.0×10² ions/cm². The drift regions 210a and 210b are separated from each other by a channel region 211 of the high-voltage semiconductor device. That is, the channel region 211 of the high-voltage semiconductor device is formed between the drift regions 210a and 210b. In the first ion implantation process for forming the drift regions 210a and 210b, a first photoresist pattern may be used as an ion implantation mask and the channel region 211 may be formed in the active region beneath the first photoresist pattern.

In an exemplary embodiment of the present invention, the semiconductor substrate 100 having the drift regions 210a and 210b may be thermally treated at a temperature of about 1,000° C. to about 1,200° C. after performing the first ion implantation process for forming the drift regions 210a and 210b.

A second ion implantation process is performed to form impurity accumulation regions 213a and 213b in the drift regions 210a and 210b, respectively. The impurity accumulation regions 213a and 213b have widths substantially narrower than those of the drift regions 210a and 210b, and have depths substantially shallower than those of the drift regions 210a and 210b. The impurity accumulation regions 213a and 213b may be formed by implanting second impurities such as, for example, phosphorus (P) with a second impurity concentration of about 1.0×10¹³ ions/cm². In the second ion implantation process for forming the impurity accumulation regions 213a and 213b, a second photoresist pattern may be used as an ion implantation mask that has a width substantially wider than a width of the channel region 211. Thus, the impurity accumulation regions 213a and 213b may be spaced apart from the channel region 211 by a predetermined interval.

In an exemplary embodiment of the present invention, the impurity accumulation regions 213a and 213b may be formed at the same time when doping impurities into a CMOS area of the semiconductor substrate 100 to adjust a threshold voltage of a transistor formed on the CMOS area. In this case, additional processes for forming the impurity accumulation regions 213a and 213b may not be required.

In an exemplary embodiment of the present invention, the impurity accumulation regions 213a and 213b may be formed in the active region of the high-voltage area, and then the drift regions 210a and 210b may be formed in the active region of the high-voltage area.

Referring to FIG. 5, a gate insulation layer and a gate conductive layer are sequentially formed on the semiconductor substrate 100.

In an exemplary embodiment of the present invention, the gate insulation layer may be formed using an oxide such as silicon oxide and the gate conductive layer may be formed using polysilicon doped with impurities.

Additionally, in another exemplary embodiment of the present invention, the gate insulation layer and the gate conductive layer may be formed using a metal oxide and a metal nitride, respectively. For example, the gate insulation layer may be formed using titanium oxide, tantalum oxide, zirconium oxide, aluminum oxide, and/or hafnium oxide, and the gate conductive layer may be formed using titanium nitride, tantalum nitride, zirconium nitride, aluminum nitride, and/or hafnium nitride.

The gate conductive layer is partially etched by a first photolithography process to form a gate conductive layer pattern 206 on the gate insulation layer. The gate conductive layer pattern 206 is positioned over the channel region 211. In the first photolithography process for forming the gate conductive layer pattern 206, the gate conductive layer pattern 206 is formed using a photoresist pattern as an etching mask after the photoresist pattern is formed on a portion of the gate conductive layer positioned directly over the channel region 211.

A silicon nitride layer is formed on the semiconductor substrate 100 to cover the resultant structure including the gate conductive layer pattern 206. The silicon nitride layer is entirely etched to form a spacer 220 on a sidewall of the gate conductive layer pattern 206. In the etching process for entirely etching the silicon nitride layer, the gate insulation layer may not be etched in the formation of the spacer 220 because the gate insulation layer has an etching selectivity with respect to the silicon nitride layer.

A buffer layer 215 is formed on the gate insulation layer, the spacer 220 and the gate conductive layer pattern 206. The buffer layer 215 may be formed using silicon nitride or silicon oxynitride. Moreover, the buffer layer 215 may be formed on the high-voltage area at the same time when an etch stop layer or a silicidation preventing layer is formed on the CMOS area. When the etch stop layer or the silicidation preventing layer is formed on the CMOS area whereas the buffer layer 215 is not simultaneously formed on the high-voltage area, processes for forming the high-voltage semiconductor device may be complicated. Thus, the buffer layer 215 may be simultaneously formed on the high-voltage area with the formation of the etch stop layer or the silicidation preventing layer on the CMOS area.

In an exemplary embodiment of the present invention, after the formation of the buffer layer 215 in the high-voltage area, a thermal treatment process for forming a metal silicide layer or an etching process for forming a contact may be performed on the CMOS area.

The buffer layer 215 and the gate insulation layer are subsequently etched so that portions of the active region of the high-voltage area for source/drain regions 209a and 209b (see FIG. 6) are exposed. Thus, a gate insulation layer pattern 205 is formed on the active region of the high-voltage area except for the source/drain regions 209a and 209b. The gate insulation layer pattern 205 may have a width substantially wider than that of the gate conductive layer pattern 206. That is, the gate insulation layer pattern 205 may be enlarged to be substantially longer than the length of the gate conductive layer pattern 206. As a result, the high-voltage semiconductor device may have improved stability when a high voltage is applied to the source/drain regions 209a and 209b.

As described above, a gate structure 208 including the gate insulation layer pattern 205 and the enlarged gate conductive layer pattern 206 is formed on the semiconductor substrate 100. The buffer layer 215 is formed on the gate insulation layer pattern 205 and the gate conductive layer pattern 206. Additionally, the spacer 220 is formed on the sidewall of the gate conductive layer pattern 206.

Referring to FIG. 6, a third ion implantation process is performed to form the source/drain regions 209a and 209b in the active region of the high-voltage area. The third ion implantation process is carried out using the gate structure 208 and the buffer layer 215 as ion implantation masks. For example, third impurities such as phosphorus (P) may be doped with an impurity concentration of about 1.0×10¹⁵ ions/cm² to form the source/drain regions 209a and 209b. The source/drain regions 209a and 209b may have widths substantially narrower than those of the impurity accumulation regions 213a and 213b. However, the source/drain regions 209a and 209b may be formed to have depths substantially deeper than those of the impurity accumulation regions 213a and 213b because the contact resistance of the high-voltage semiconductor device may be deteriorated when the depths of the source/drain regions 209a and 209b are shallower than those of the impurity accumulation regions 213a and 213b.

The source/drain regions 209a and 209b are adjacent to the impurity accumulation regions 213a and 213b whereas the source/drain regions 209a and 209b are spaced apart from the channel region 211 by a predetermined interval.

Also, in an exemplary embodiment of the present invention, the source/drain regions 209a and 209b may be formed in the active region of the high voltage area, and then the impurity accumulation regions 213a and 213b may formed to be adjacent to the source/drain regions 209a and 209b.

Additionally, in another exemplary embodiment of the present invention, arbitrary regions of the drift regions 210a and 210b, the impurity accumulation regions 213a and 213b and the source/drain regions 209a and 209b may be previously formed in the active region of the high-voltage area, and then other regions may be formed in the active region of the high-voltage area.

Referring to FIG. 7, an insulation layer is formed on the semiconductor substrate 100 to cover the resultant structure including the gate structure 208 and the buffer layer 215. The insulation layer may serve as an insulating interlayer. The insulation layer may be formed using, for example, a silicon oxide such as boro-phosphor silicate glass (BPSG) through a plasma-enhanced chemical vapor deposition (PECVD) process. The insulation layer may be planarized by a planarization process including a chemical mechanical polishing (CMP) process and/or an etch back process.

The insulation layer is partially removed to form a second insulation layer pattern 224 having openings 225 that partially expose the source/drain regions 209a and 209b. The insulation layer pattern 224 may be formed through a photolithography process using a photoresist pattern as an etch mask.

A conductive layer is formed on the insulation layer pattern 224 to fill up the openings 225a and 225b. The conductive layer is partially etched to form conductive layer patterns 226a and 226b filling up the openings 225a and 225n on the insulation layer pattern 224. The conductive layer patterns 226a and 226b may correspond to metal wires, respectively. The conductive layer patterns 226a and 226b may be formed through a photolithography process. Moreover, each of the conductive layer patterns 226a and 226b may include a barrier metal layer pattern, a contact plug and a metal line connected to the contact plug.

Further, according to an exemplary embodiment of the present invention, various insulation and conductive structures may be formed on the conductive layer patterns 226a and 226b and the insulation layer pattern 224 to thereby complete the high-voltage semiconductor device in the high-voltage area of the semiconductor substrate 100.

In the formation of the high-voltage semiconductor device according to some exemplary embodiments of the present invention, a CMOS device may be formed in a CMOS area of the semiconductor substrate 100. The CMOS device may include, for example, a gate insulation layer pattern, a gate conductive layer pattern, an insulation layer pattern, and a conductive layer pattern. Elements of the CMOS device may be simultaneously formed together with corresponding elements of the high-voltage semiconductor device.

Although the above exemplary embodiments of the invention describe manufacturing a high-voltage semiconductor device corresponding to a NMOS type high-voltage semiconductor device, other high-voltage semiconductor devices, such as for example, PMOS type high-voltage semiconductor devices may also be formed in the high-voltage area of the semiconductor substrate 100 in accordance with exemplary embodiments of the invention as well by, for example, doping P type impurities into the deep well region 102, the drift regions 210a and 210b, and the source/drain regions 209a and 209b.

### Tests for a Variation of a Current Relative to Time

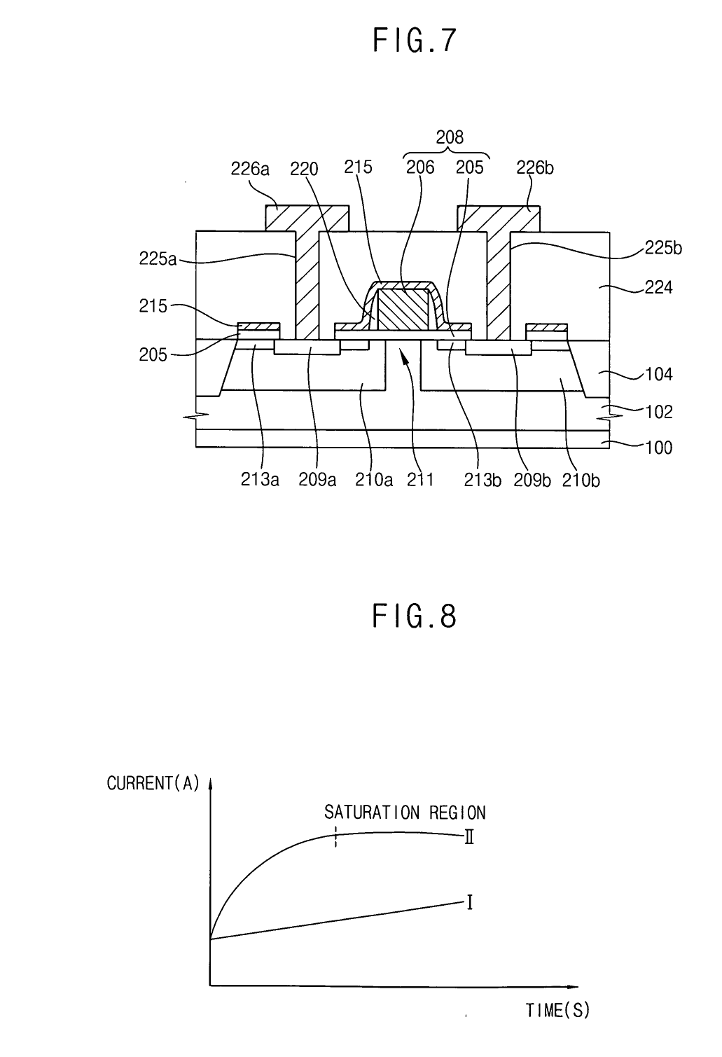

FIG. 8 is a graph showing a variation of a current relative to time in a conventional high-voltage semiconductor device and a high-voltage semiconductor device according to an exemplary embodiment of the present invention.

In FIG. 8, a first curve I indicates a variation of current relative to time in the high-voltage semiconductor device of an exemplary embodiment of the present invention. The first curve I is obtained by applying a voltage of about 30 V to a source region of the high-voltage semiconductor device and by applying a voltage of about 30 V to a gate conductive layer pattern of the high-voltage semiconductor device. A second curve II represents a variation of a current relative to time in the conventional high-voltage semiconductor device. The second curve II is obtained by applying a voltage of about 30 V to a source region of the conventional high-voltage semiconductor device and by applying a voltage of about 30 V to a gate conductive layer pattern of the conventional high-voltage semiconductor device.

As shown in FIG. 8, the current in the conventional high-voltage semiconductor device is rapidly increased as time goes by. Thus, the current of the conventional high-voltage semiconductor maintains a saturated value. However, the current in the high-voltage semiconductor device of the present exemplary embodiment of the invention has a substantially constant value regardless of time. Therefore, the high-voltage semiconductor device of the present exemplary embodiment of the invention may prevent a rapid increase of the current caused by charge trapping sites.

According to exemplary embodiments of the present invention, a high-voltage semiconductor device includes impurity accumulation regions adjacent to source/drain regions wherein the impurity accumulation regions have impurity concentrations substantially smaller than those of the source/drain regions. Thus, current flowing in the high-voltage semiconductor device may not be rapidly increased even though charge trapping sites are generated at an interface between a buffer layer and a gate insulation layer pattern. As a result, the electrical reliability of the high-voltage semiconductor device may be significantly improved in comparison to conventional high-voltage semiconductor devices when the buffer layer in a high-voltage area of a semiconductor substrate is formed together with an etch stop layer or a silicidation preventing layer formed in a CMOS area of the semiconductor substrate.

Additionally, with exemplary embodiments of the invention, a high-voltage semiconductor device having improved electrical reliability and a CMOS device having a minute structure may be formed on one semiconductor substrate.

Having described the exemplary embodiments of the present invention, it is further noted that it is readily apparent to those of reasonable skill in the art that various modifications may be made without departing from the spirit and scope of the invention that is defined by the appended claims.

What is claimed is:

1. A high-voltage semiconductor device comprising:
a semiconductor substrate;
a plurality of drift regions formed in the semiconductor substrate, each of the plurality of drift regions formed having a first impurity, a first impurity concentration and a first depth, wherein the drift regions are separate from each other to define a channel region between the drift regions;
a source region and a drain region formed at first portions of the drift regions, the source region and the drain region formed each having a second impurity, a second impurity concentration and a second depth, wherein the second depths of the source/drain regions are substantially smaller than the first depths;
a plurality of impurity accumulation regions formed at second portions of the drift regions adjacent to the source/drain regions, each of the plurality of impurity accumulation regions formed having a third impurity, a third impurity concentration and a third depth, wherein the thirds depths of the impurity accumulation regions are substantially smaller than the first depths,;
a gate structure formed on the semiconductor substrate, wherein the gate structure comprises a gate insulation layer pattern formed on the semiconductor substrate to partially expose the source/drain regions, and a gate conductive layer pattern formed on a portion of the gate insulation layer pattern where the channel region is positioned; and
a buffer layer formed on the gate structure.

2. The high-voltage semiconductor device of claim 1, wherein the semiconductor device further comprises an isolation layer for dividing the semiconductor substrate into an active region and a field region, wherein the channel region, the drift regions and the gate structure are positioned on the active region.

3. The high-voltage semiconductor device of claim 1, wherein the first, the second and the third impurities comprise substantially the same elements.

4. The high-voltage semiconductor device of claim 3, wherein the first, the second and the third impurities comprise elements in Group III.

5. The high-voltage semiconductor device of claim 3, wherein the first, the second and the third impurities comprise elements in Group V.

6. The high-voltage semiconductor device of claim 1, wherein the second impurity concentrations are substantially larger than the third impurity concentrations, and the third impurity concentrations are substantially larger than the first impurity concentrations.

7. The high-voltage semiconductor device of claim 1, wherein the second depths are substantially larger than the third depths.

8. The high-voltage semiconductor device of claim 1, wherein the source/drain regions are spaced apart from the channel region.

9. The high-voltage semiconductor device of claim 1, wherein the impurity accumulation regions are adjacent to the source/drain regions whereas the impurity accumulation regions are spaced apart from the channel region.

10. The high-voltage semiconductor device of claim 1, wherein the gate insulation layer pattern comprises silicon oxide or metal oxide layer, the gate conductive layer pattern comprises metal, metal nitride or polysilicon doped with impurities, and the buffer layer comprises silicon nitride or silicon oxynitride.

11. The high-voltage semiconductor device of claim 1, further comprising a deep well region formed in the semiconductor substrate to enclose the channel region and the drift regions, the well region having a fourth impurity which is different from the first impurities and a fourth impurity concentration substantially smaller than the first impurity concentrations, wherein the deep well region has a fourth depth substantially larger than the first depth.

12. A method of manufacturing a high-voltage semiconductor device, the method comprising:
forming a plurality of drift regions in a semiconductor substrate by doping first impurities with first impurity concentrations into the semiconductor substrate, such that each of the plurality of drift regions formed have a first impurity, a first impurity concentration and a first depth, and wherein the drift regions are spaced apart from each other to define a channel region between the drift regions;
forming a source region and a drain region at first portions of the drift regions by doping second impurities with second impurity concentrations into the first portions of the drift regions such that the source region and the drain region formed each have a second impurity, a second impurity concentration and a second depth, and wherein the second depths of the source/drain regions are substantially smaller than the first depths;
forming a plurality of impurity accumulation regions at second portions of the drift regions adjacent to the source/drain regions by doping third impurities with third impurity concentrations into the second portions of the drift regions adjacent to the source/drain regions such that each of the plurality of impurity accumulation regions formed have a third impurity, a third impurity concentration and a third depth, and wherein the third depths of the impurity accumulation regions are substantially smaller than the first depths;
forming a gate insulation layer pattern on the semiconductor substrate, wherein the gate insulation layer pattern has openings that partially expose the source/drain regions;
forming a gate conductive layer pattern on a portion of the gate insulation layer pattern where the channel region is positioned; and
forming a buffer layer on the gate insulation layer pattern and the gate conductive layer pattern.

13. The method of claim 12, wherein the first, the second and the third impurities comprise substantially the same elements.

14. The method of claim 13, wherein first, the second and the third impurities comprise elements in Group III.

15. The method of claim 13, wherein first, the second and the third impurities comprise elements in Group V.

16. The method of claim 12, wherein the second impurity concentrations are substantially larger than the third impurity concentrations, and the third impurity concentrations are substantially larger than the first impurity concentrations.

17. The method of claim 12, wherein the second depths are substantially larger than the third depths.

18. The method of claim 12, wherein the source/drain regions are spaced apart from the channel region.

19. The method of claim 12, wherein the impurity accumulation regions are adjacent to the source/drain regions whereas the impurity accumulation regions are spaced apart from the channel region.

20. The method of claim 12, wherein the gate insulation layer pattern comprises silicon oxide or metal oxide layer, the gate conductive layer pattern comprises metal, metal nitride or polysilicon doped with impurities, and the buffer layer comprises silicon nitride or silicon oxynitride.

21. The method of claim 12, further comprising:
forming an isolation layer at an upper portion of the semiconductor substrate to define an active region and a field region; and
forming a deep well region in the semiconductor substrate to enclose the channel region and the drift regions by doping impurities different from the first impurities with an impurity concentration substantially smaller than the first impurity concentrations, wherein the deep well region has a fourth depth substantially larger than the first depths.

22. The method of claim 12, wherein forming the impurity accumulation regions are performed together with doping impurities for adjusting a threshold voltage into a portion of the semiconductor substrate adjacent to the high-voltage semiconductor device.

23. The method of claim 12, wherein forming the buffer layer is performed together with forming an etch stop layer or a silicidation preventing layer on a portion of the semiconductor substrate adjacent to the high-voltage semiconductor substrate.
